(19) United States
(12) Patent Application Publication
(10) Pub. No.: US 2007/0190438 A1
(43) Pub. Date: Aug. 16, 2007

(54) METHOD AND APPARATUS FOR CONTROLLING LIGHT INTENSITY AND FOR EXPOSING A SEMICONDUCTOR SUBSTRATE

(75) Inventors: Kye-Weon KIM, Gyeonggi-do (KR); Yu-Sin YANG, Seoul (KR); Chung-Sam JUN, Gyeonggi-do (KR); Yong-Wan KIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/675,016

(22) Filed: Feb. 14, 2007

(30) Foreign Application Priority Data
Feb. 15, 2006 (KR) 2006-14414

(51) Int. Cl. G03F 1/00; G03C 5/00; G03B 27/42

(52) U.S. Cl. 430/30; 430/5; 355/53

(57) ABSTRACT

In an embodiment, a method of controlling a light intensity includes measuring a critical dimension distribution of a pattern on a substrate. The critical dimension distribution is formed using a first illumination having a first intensity distribution, which is irradiated onto the substrate through a photo mask. A second intensity distribution of the first illumination by regions of the photo mask, which is used for forming a pattern having uniform dimensions on the substrate, is then obtained based on a relation between the first intensity distribution and the critical dimension distribution. The first illumination having the first intensity distribution is converted into a second illumination having the second intensity distribution as by interposing an array of light controlling elements (e.g., LCD pixels, or motorized polarizing elements) within the light path.

### CROSS-REFERENCE TO RELATED APPLICATIONS

This application claims priority under 35 USC §119 to Korean Patent Application No. 2006-14414, filed on Feb. 15, 2006, the contents of which are herein incorporated by reference in their entirety for all purposes.

### BACKGROUND

1. Field of the Invention

Example embodiments relate to a method and an apparatus for controlling light intensity, and a method and an apparatus for exposing a semiconductor substrate. More particularly, example embodiments relate to a method of controlling light intensity that is capable of forming a pattern having uniform critical dimensions on a semiconductor substrate, an apparatus for performing the controlling method, a method of exposing a semiconductor substrate using the controlling method, and an apparatus for performing the exposing method.

2. Description of the Related Art

A photolithography process is one of several key semiconductor device manufacturing processes forming a photoresist pattern on a semiconductor substrate. The photolithography process generally includes a photoresist coating process for forming a photoresist film on the semiconductor substrate, a baking process for hardening the photoresist film, and an exposure and developing process for forming a photoresist pattern from the hardened photoresist film using a photo mask.

The exposure process is performed by selectively exposing the photoresist film on the semiconductor substrate to light. The photoresist pattern is formed by transferring a mask pattern into the photoresist film using the light that is generated in a light source.

As the semiconductor device becomes smaller, a macro-defect of the mask pattern may cause a macro non-uniformity of critical dimensions of the photoresist pattern. To solve the above-mentioned problem, according to conventional arts, an exposure apparatus may be improved to form a photo mask having uniform dimensions or the problem photo mask may simply be discarded and replaced by a better one. Another conventional solution includes forming a plurality of holes having a regular depth on a backside of the photo mask to control an intensity of the light that transmits through the photo mask. In this way, the intensity of the light exposing the photoresist film may be individually controlled at each part of the photo mask.

However, regardless of these conventional improvements in the exposure method and apparatus, the causes that generate the macro-defects in the mask pattern may not be eliminated. And to form the holes on the photo mask, an additional process for performing a physical treatment on the photo mask may be required. Because of this physical treatment, as an exposure process is repeatedly performed, a surface of the photo mask is deteriorated by the intense light having a high energy, and surface defects of the photo mask such as a haze may be generated.

Accordingly, an improved system for effecting controlled illumination through a potentially defective or damaged photo mask is desired.

### SUMMARY

Example embodiments provide a method of controlling a light intensity that is capable of forming a pattern having uniform critical dimensions on a semiconductor substrate.

Example embodiments also provide an apparatus for performing the above-mentioned controlling method.

Example embodiments also provide a method of exposing a semiconductor substrate that is capable of forming a pattern having uniform critical dimensions on a semiconductor substrate.

Example embodiments also provide an apparatus for performing the above-mentioned exposing method.

In a method of controlling a light intensity in accordance with one aspect, a critical dimension distribution of a first pattern formed on a substrate is obtained. The pattern is formed using a first light having a first intensity distribution that is irradiated onto the substrate through a photo mask. A second intensity distribution is calculated according to regions of the photo mask. The calculation is based on a relation between the first intensity distribution according to the regions of the photo mask and the critical dimension distribution. The second intensity distribution is used for forming a second pattern having uniform critical dimensions on the substrate. The first illumination is converted to a second illumination having the second intensity distribution.

According to one example embodiment, converting the first illumination into the second illumination may include selectively controlling an intensity of the first illumination having the first intensity distribution in accordance with the regions of the photo mask. Further, controlling the intensity of the first illumination may include decreasing light transmissivity of each of light transmitting elements in a light transmission element array having a variable light transmissivity.

According to another example embodiment, the controlling method may further include storing data of the second intensity distribution in accordance with the regions of the photo mask.

According to still another example embodiment, obtaining the second intensity distribution may include setting a reference critical dimension among the critical dimensions, comparing the critical dimensions with the reference critical dimension to obtain a deviation of the critical dimensions, obtaining a variation of the critical dimensions in accordance with the first intensity distribution, and obtaining the second intensity distribution based on the deviation and the variation of the critical dimensions.

An apparatus for controlling a light intensity in accordance with another aspect includes an optical unit for selectively controlling an intensity of a first illumination, which is irradiated to a photo mask having a mask pattern, in accordance with regions of the photo mask. A detecting unit detects a critical dimension distribution of a pattern on a semiconductor substrate that is formed using the first illumination having a first intensity distribution transmitted through the photo mask. A calculating unit calculates a second intensity distribution of the first illumination, which is used for forming a pattern having uniform dimensions, based on a relation between the first intensity distribution and the critical dimension distribution. A controlling unit controls the optical unit to convert the first illumination having the first intensity distribution into a second illumination having the second intensity distribution.

According to an example embodiment, the optical unit may include a light transmission element array that has a plurality of mesh-type light transmission elements having a variable light transmissivity, and a controller for respectively controlling the light transmissivity of the light transmission elements to vary the first intensity distribution of the first illumination in accordance with the regions of the photo mask. Each of the light transmission elements may include a polarizing device, and the controller may include a plurality of motors for rotating the polarizing devices. Alternatively, each of the light transmission elements may include a liquid crystal device, and the controller may include a plurality of voltage converters for controlling a voltage that is applied to the liquid crystal devices.

According to still another example embodiment, the controlling apparatus may further include a data storing unit for storing data of the second intensity distribution therein.

According to still another example embodiment, the calculating unit may include a reference setter for setting a reference critical dimension among the critical dimensions, a first calculator for calculating a deviation of the critical dimensions by comparing the reference critical dimension with the critical dimensions, a second calculator for calculating a variation of the critical dimensions based on the first intensity distribution of the first illumination by the regions of the photo mask, and a third calculator for calculating the second intensity distribution based on the deviation and the variation of the critical dimensions.

In a method of exposing a semiconductor substrate in accordance with still another aspect of the present invention, a first exposure process is performed on a substrate using a first illumination having a first intensity distribution, which is transmitted through a photo mask, to form a pattern on the substrate. A critical dimension distribution of the pattern is then measured. A second intensity distribution of the first illumination by regions of the photo mask, which is used for forming a pattern having uniform dimensions on the substrate, is then obtained based on a relation between the first intensity distribution and the critical dimension distribution. The first illumination having the first intensity distribution is converted into a second illumination having the second intensity distribution. A second exposure process is carried on the substrate using the second illumination having the second intensity distribution to form the pattern having the uniform dimensions on the substrate.

According to one example embodiment, converting the first illumination into the second illumination may include selectively controlling an intensity of the first illumination having the first intensity distribution in accordance with the regions of the photo mask. Further, controlling the intensity of the first illumination may include decreasing light transmissivity of each of light transmitting elements in a light transmission element array having a variable light transmissivity.

In an apparatus of exposing a semiconductor substrate in accordance with still another aspect includes a light source for generating a first illumination that is irradiated to a substrate through a photo mask having a mask pattern. An optical unit selectively controls an intensity of the first illumination, which is irradiated to a photo mask having a mask pattern, in accordance with regions of the photo mask. A detecting unit detects a critical dimension distribution of a pattern on a semiconductor substrate that is formed using the first illumination having a first intensity distribution transmitted through the photo mask. A calculating unit calculates a second intensity distribution of the first illumination, which is used for forming a pattern having uniform dimensions, based on a relation between the first intensity distribution and the critical dimension distribution. A controlling unit controls the optical unit to convert the first illumination having the first intensity distribution into a second illumination having the second intensity distribution.

According to an example embodiment, the optical unit may include a light transmission element array that has a plurality of mesh-type light transmission elements having a variable light transmissivity, and a controller for respectively controlling the light transmissivity of the light transmission elements to vary the first intensity distribution of the first illumination in accordance with the regions of the photo mask.

According to the present invention, the first illumination having the first intensity distribution irradiated to each of the regions of the photo mask may be converted into the second illumination having the second intensity distribution. Thus, the pattern having the uniform dimensions may be formed using the second illumination having the second intensity distribution.

### BRIEF DESCRIPTION OF THE DRAWINGS

The above and other features and advantages of the invention will become readily apparent by reference to the following detailed description when considered in conjunction with the accompanying drawings wherein:

FIG. 1 is a block diagram illustrating an apparatus for controlling a light intensity in accordance with an example embodiment of the present invention;

FIG. 2 is a perspective view illustrating a light transmission element array in FIG. 1;

FIG. 3 is a plan view illustrating the light transmission element of FIG. 2;

FIG. 4 is a block diagram illustrating the calculating unit of FIG. 1;

FIG. 5 is a flow chart illustrating a method of controlling a light intensity using the apparatus in FIG. 1 according to an aspect of the invention;

FIG. 6 is a flow chart illustrating a method of obtaining a light intensity distribution for the method of FIG. 5 according to a preferred embodiment of the invention;

FIG. 7 is a block diagram illustrating an apparatus for exposing a semiconductor substrate in accordance with another example embodiment of the present invention; and

FIG. 8 is a flow chart illustrating a method of exposing a semiconductor substrate using the apparatus in FIG. 7 according to an aspect of the invention.

### DESCRIPTION OF THE EMBODIMENTS

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

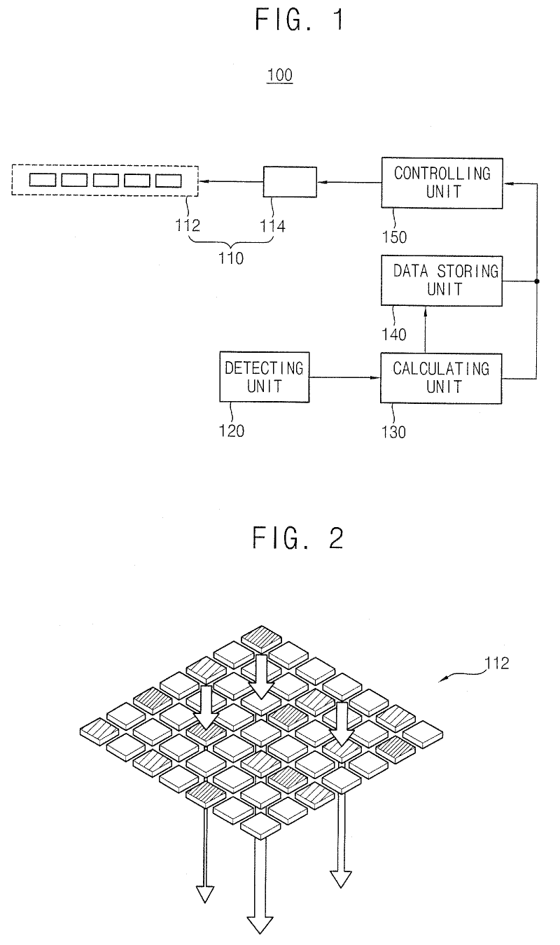

FIG. 1 is a block diagram illustrating an apparatus for controlling a light intensity in accordance with an example embodiment.

An apparatus 100 for controlling the light intensity in accordance with this example embodiment includes an optical unit 110, a detecting unit 120, a calculating unit 130, a data-storing unit 140, and a controlling unit 150.

The optical unit 110 controls the transmissivity of light emitted from a light source (not shown) to control its intensity distribution. The light controlled by the optical unit 110 is irradiated onto a photo mask (not shown) having a mask pattern. The optical unit 10 may selectively reduce the light intensity according to regions of the photo mask. As a result, the light intensity may vary according to the regions of the photo mask.

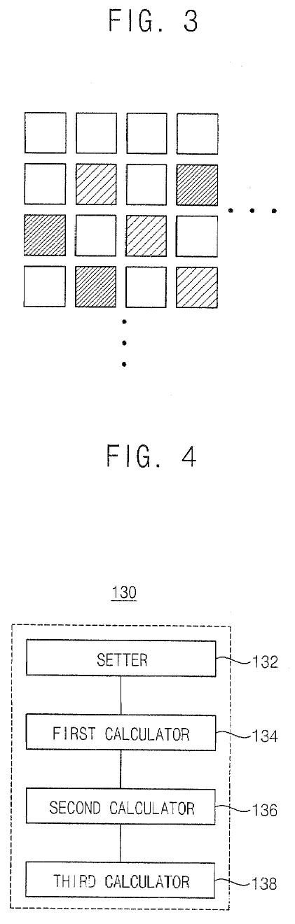

FIGS. 2 and 3 are views illustrating the light transmission element array in the embodiment of FIG. 1.

Referring to the figures, the optical unit 110 includes a light transmission element array 112 and a controller 114. The light transmission element array 112 may include a plurality of mesh-type light transmission elements that are arranged substantially perpendicular to the propagating direction of the light. Each of the light transmission elements controls the intensity of the light in that portion passing through it. In this example embodiment, the light transmission elements may transmit wholly the light to maintain the light intensity, or the light transmission elements may partially transmit the light to reduce the light intensity.

The controller 114 may be connected to the light transmission element array 112 to respectively control the transmissivity of the light transmission elements. Thus, the light transmission element array 112 controls the intensity of the light irradiated onto the photo mask using the controller 114. The light transmission elements corresponding to the regions of the photo mask where a relatively low light intensity is required can greatly reduce the light intensity to these regions. On the other hand, the light transmission elements corresponding to the regions of photo mask where a relatively high light intensity is required can be configured to transmit most or all light received therethrough, thereby minimizing the light reduction. In this way, the transmissivity of the light transmission elements may control an intensity distribution of the light over all the regions of the photo mask.

In this example embodiment, the light transmission element array 112 and the controller 114 may include a polarizing element array and a motor, respectively. Each of a plurality of polarizing elements of the polarizing element array can have varying degrees of transmissivity by adjusting their direction of polarization. The motor may be used to rotate the polarizing elements. In this way, the light intensity distribution of the light irradiated onto the photo mask is adjusted by controlling the rotation of each of the polarizing elements. Other methods of controlling the transmissivity of the elements of the array can be realized by one skilled in the art, and other examples are now explained.

In another example embodiment, the first illumination transmission element array 112 and the controller 114 may be a liquid crystal element array and a voltage converter, respectively. A plurality of liquid crystal elements of the array has a molecular arrangement that is irregular in one direction and regular in another direction. The voltage converter varies a voltage provided to each of the liquid crystal elements. A regularity of the molecular arrangement in the liquid crystal elements is changed in accordance with the voltage provided to the liquid crystal elements. The intensity distribution of the light irradiated through the transmission element array 112 and onto the photo mask is controlled by adjusting the voltage provided to the liquid crystal elements. FIGS. 2 and 3 illustrate this exemplary transmissivity by the density of the cross-hatch lines in each square region of array 112-full transmissivity (e.g. transparent elements) are represented by the clear squares and severe illumination reduction is shown by the densely cross-hatched squares.

The detecting unit 120 obtains a critical dimension distribution of a pattern on the semiconductor substrate that is formed by the photo mask. The detecting unit 120 does this by detecting an image of the pattern. The pattern is formed using the first illumination having a first intensity distribution, which is irradiated onto the semiconductor substrate through the photo mask. The critical dimension distribution detected by the detecting unit 120 may be displayed in any form, including a map or other schematic-type drawing. Here, the critical dimension distribution detected by the detecting unit 120 may be non-uniform, which would be represented in a display. The detecting unit 120 may include an image sensor.

The calculating unit 130 calculates a second intensity distribution of the first illumination using the critical dimension distribution. The second intensity distribution is used for forming a pattern having uniform dimensions on the semiconductor substrate. Here, the critical dimension distribution is related to the first intensity distribution. That is, when the first intensity distribution is changed, the critical dimension of the pattern on the semiconductor substrate is also changed. The calculating unit 130 calculates the second intensity distribution based on the relation between the critical dimension distribution and the first intensity distribution.

FIG. 4 is a block diagram illustrating the calculating unit of FIG. 1.

The calculating unit 130 includes a reference setter 132, a first calculator 134, a second calculator 136, and a third calculator 138. The reference setter 132 sets a reference critical dimension among the reference critical dimensions detected by the detecting unit 120. The reference critical dimension may correspond to a maximum critical dimension.

Corresponding to regions of the photo mask where a relatively high light intensity is irradiated, the critical dimension of the pattern is relatively small. Correspondingly, the critical dimension of the pattern corresponding to regions of the photo mask where a relatively low light intensity is irradiated is relatively large. The optical unit 110 can maintain or reduces the light intensity of the light irradiated onto the photo mask. Because the reference critical dimension corresponds to a maximum critical dimension, the pattern may have uniform critical dimensions by reducing the light intensity of the light irradiated on the photo mask.

The first calculator 134 compares the reference critical dimension with the critical dimensions of the pattern to calculate a deviation. The deviation of the critical dimensions may be obtained using an equation for this purpose, familiar to one skilled in the art.

The second calculator 136 calculates the intensity distribution of the light irradiated onto the photo mask, and also calculates the variation of the critical dimensions of the pattern based on the intensity distribution. The intensity distribution may be calculated in terms of the photo mask regions using the pattern's critical dimension distribution and a mask pattern size distribution. The variation of the critical dimensions of the pattern based on the light intensity may be calculated using the light intensity distribution of the light irradiated on the photo mask and the critical dimensions distribution of the pattern.

The third calculator 138 calculates the second intensity distribution of the light, which is irradiated onto the photo mask. The calculation is based on the deviation of the critical dimensions and the variation of the critical dimensions due to the light intensity distribution. The goal of the calculation is to reduce the deviation of the critical dimensions.

Data of the second intensity distribution are stored in the data-storing unit 140. Thus, when the data of the second intensity distributions with respect to various illuminations are obtained, a database of such values may be included in the data-storing unit 140.

The controlling unit 150 controls the optical unit 110 in accordance with the second intensity distribution calculated by the calculating unit 130. That is, the controlling unit 150 controls the driver 114 to modify a second illumination having the second intensity distribution onto the photo mask. Thus, the pattern may have uniform critical dimensions.

The pattern having the uniform critical dimensions may be formed on the semiconductor substrate by controlling the intensity of the light irradiated onto the photo mask.

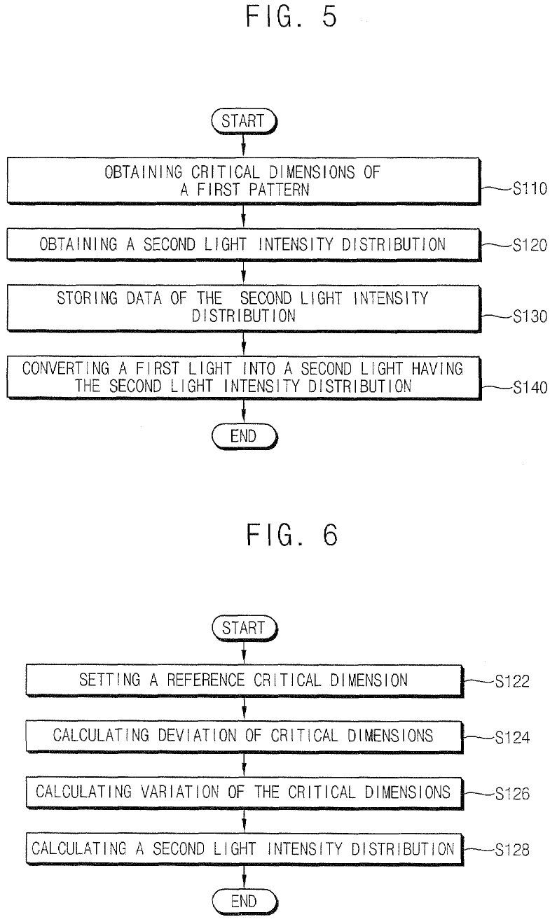

FIG. 5 is a flow chart illustrating a method of controlling a light intensity using the apparatus in FIG. 1.

In step S110, the first illumination having the first intensity distribution is irradiated onto the semiconductor substrate through the photo mask having the mask pattern to form the pattern on the semiconductor substrate. Here, the pattern may have non-uniform critical dimensions. The critical dimension distribution is detected using the image of the pattern on the semiconductor substrate. The critical dimension distribution is displayed in a map based on the detected intensity.

In step S120, the calculating unit 130 calculates the second intensity distribution based on the relation between the critical dimension distribution and the first intensity distribution. The second intensity distribution corresponds to a light intensity distribution used for forming a pattern having uniform critical dimensions.

FIG. 6 is a flow chart illustrating a method of obtaining a light intensity distribution in FIG. 5.

Referring to FIG. 6, in step S122, the maximum critical dimension is selected among the critical dimensions indicated in the map. The reference setter 132 sets the maximum critical dimension as the reference critical dimension.

In step S124, the first calculator 134 compares the reference critical dimension with the critical dimensions to calculate the deviation of the critical dimensions.

In step S126, the second calculator 136 calculates the light intensity distribution according to the regions of the photo mask using the critical dimension distribution of the pattern and a mask pattern size distribution. The second calculator 136 calculates the variation of the critical dimensions of the pattern based on the first intensity distribution of the first illumination irradiated on the photo mask and the critical dimension distribution of the pattern.

In step S128, the third calculator 138 calculates the second intensity distribution of the first illumination, which is to be irradiated onto the photo mask. The calculation is used to reduce the deviation of the critical dimensions by using the variation of the critical dimensions of the pattern in accordance with the deviation of the critical dimensions and the first intensity distribution.

Referring back to FIG. 5, in step S130, the second intensity distributions obtained from various illuminations are stored in the data-storing unit 140 to constitute the database in the storing unit 140. The second intensity distributions are stored in accordance with the photo mask.

In step S140, the controlling unit 150 controls the driver 114 of the optical unit 110 based on the second intensity distribution calculated by the calculating unit 130. Alternatively, the controlling unit 150 may use intensity distributions stored in the data-storing unit 140.

The driver 114 controls the light transmission elements of the first illumination transmission element array. The transmissivity of the light transmission elements is controlled. Thus, the first illumination irradiated from the light source is converted into the second illumination having the second intensity distribution.

The pattern having uniform critical dimensions may be formed on the semiconductor substrate by controlling the intensity of the light irradiated onto the photo mask.

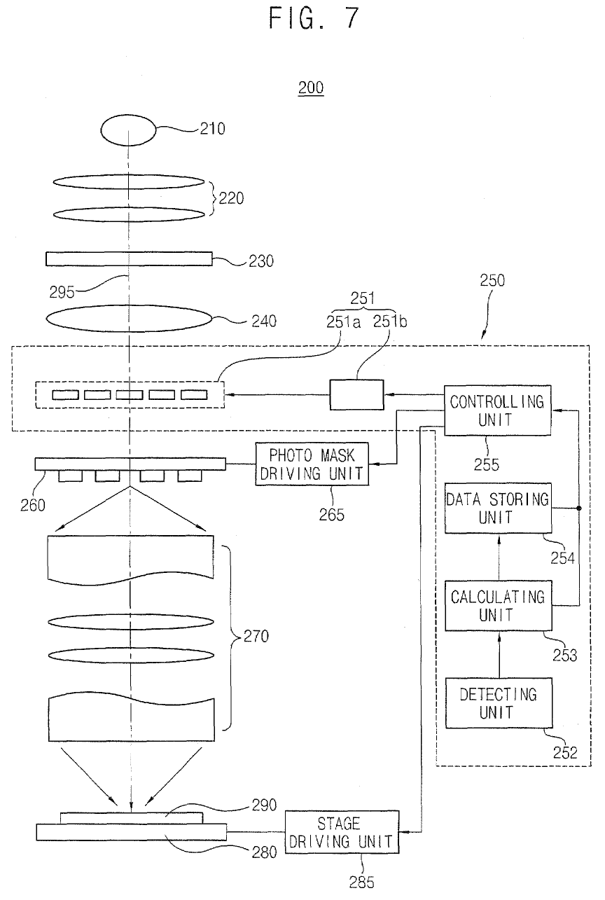

FIG. 7 is a block diagram illustrating an apparatus for exposing a semiconductor substrate in accordance with another example embodiment.

An apparatus 200 for exposing a semiconductor substrate 290 in accordance with the present embodiment includes a light source 210, a condensing lens unit 220, a fly's eye lens array 230, an illuminating lens 240, a light intensity-controlling unit 250, a photo mask 260, and a projection lens unit 270.

The light source 210 generates the light irradiated onto the semiconductor substrate 290 having a photoresist film. Examples of the light source 210 include a lamp or a laser. In this example embodiment, the light source 210 may emit a G-line light beam having a wavelength of about 436 nm, an 1-line light beam having a wavelength of about 365 m, a KrF excimer laser beam having a wavelength of about 248 nm, an ArF excimer laser beam having a wavelength of about 198 nm, an F₂ excimer laser beam having a wavelength of about 157 nm, and so on.

Here, an optical axis 295 extends between the light source 210 and the semiconductor substrate 290, through centers of the illuminating lens 240 and the projection lens 270.

The condensing lens unit 220 condenses the light emitted from the light source 210. The fly's eye lens array 230 diffuses the condensed light to uniformly irradiate the condensed light onto the semiconductor substrate 290. The illuminating lens 240 condenses the light passed the fly's eye lens array 230.

The light controlling unit 250 controls the light condensed at the illuminating lens 240 and irradiated onto the photo mask 260 having a mask pattern. The light-controlling unit 250 includes an optical unit 251, a detecting unit 252, a calculating unit 253, a data-storing unit 254, and a controlling unit 255.

One embodiment of the light-controlling unit 250 is illustrated in detail with reference to FIGS. 1 to 4. Thus, any further illustrations of the light-controlling unit 250 are omitted herein for brevity.

The light having the light intensity distribution controlled by the light-controlling unit 250 is irradiated onto the photo mask 260. A photo mask driving unit 265 moves the photo mask 260 in an X-axis.

Additionally, a slit (not shown) for adjusting a width of the light may be arranged between the illuminating lens 240 and the photo mask 260.

The light passing through the photo mask 260 is focused by the projecting lens unit 270 onto the semiconductor substrate 290 that is placed on a stage 280. A stage-driving unit 285 moves the stage 280 along an X-axis and a Y-axis. In an exposure process, the stage 280 and the photo mask 260 are moved along the X-axis in opposite directions from each other.

As a result, the mask pattern of the photo mask 260 is transcribed into a photoresist film on the semiconductor substrate 290.

When the light intensity is relatively high or when any other similar effects are applied in the exposure process, the photoresist pattern will have a region with relatively small critical dimensions. The apparatus 200 reduces the light intensity using the light controlling unit 250 corresponding to this region of the photoresist pattern. Thus, the photoresist pattern may have uniform critical dimension by effectively increasing the critical dimensions in one region to match those of another region.

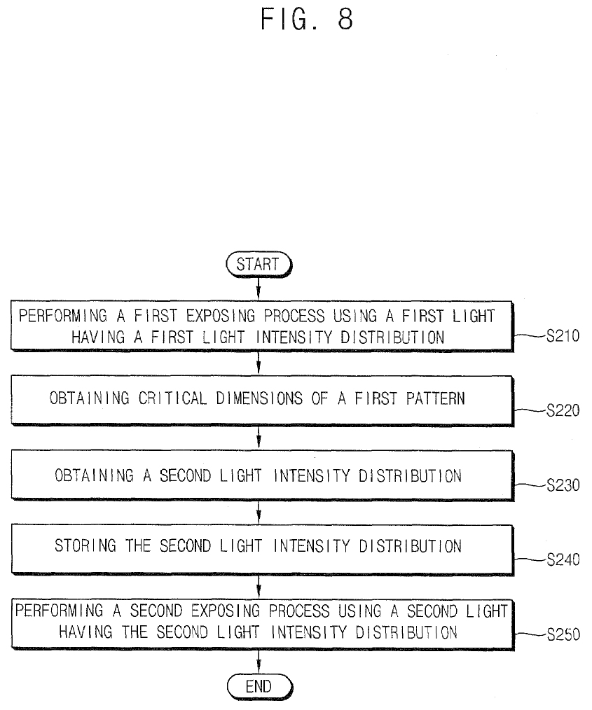

FIG. 8 is a flow chart illustrating a method of exposing a semiconductor substrate using the apparatus in FIG. 7.

In step S210, a first exposure process is carried out. In this example embodiment, the first illumination emitted from the light source 210 is irradiated to the condensing lens 220 and is then condensed. The condensed first illumination is irradiated to the fly's eye lens array 230. The first illumination passing through the fly's eye lens array 230 is irradiated to the illuminating lens 240. The first illumination passing through the illuminating lens 240 is irradiated to the light transmission element array 251a of the optical unit 251. The light transmission element array 251a passes the first illumination so that the intensity of the first illumination is not yet reduced. The first illumination having the first intensity distribution is irradiated to the photo mask 250. The first illumination passing through the photo mask 260 is irradiated onto the semiconductor substrate 290.

As mentioned above, when the light intensity is relatively high or when any other similar effects are applied in the exposure process, the photoresist pattern has a region that has relatively small critical dimensions. Thus, the first pattern may have non-uniform critical dimensions. In step S220, the detecting unit 252 detects the critical dimension distribution of the first illumination using the image of the semiconductor substrate 290. The critical dimension distribution of the first pattern is displayed in a map based on the detected intensity.

In step S230, the calculating unit 253 calculates the second intensity distribution based on the relation between the critical dimension distribution and the first intensity distribution. The second intensity distribution corresponds to the light intensity distribution used for forming the pattern having uniform critical dimensions.

Here, the process for obtaining the second intensity distribution is substantially identical to that illustrated with reference to FIGS. 5 and 6. Thus, any further illustrations of the process are omitted herein for brevity.

In step S240, the second intensity distributions obtained from various illuminations are stored in the data-storing unit 254 that constitutes the database in the data-storing unit 254.

The controlling unit 255 controls the driver 251b of the optical unit 251 based on the second intensity distribution calculated by the calculating unit 253. Alternatively, the controlling unit 255 may control the driver 251b based on the second intensity distributions stored in the data-storing unit 254.

In step S250, a second exposure process is performed. In this example embodiment, the controlling unit 255 adjusts the transmissivity of the light transmission elements of the light transmission element array 251a. The second illumination emitted from the light source 210 is controlled by the light transmission elements. The controlled second illumination is irradiated to the condensing lens 220 and is then condensed. The condensed second illumination is irradiated to the fly's eye lens array 230. The second illumination passing through the fly's eye lens array 230 is irradiated to the illuminating lens 240. The second illumination passing through the illuminating lens 240 is irradiated to the light transmission elements of the light transmission element array 251a. The light transmission element array 251a selectively reduces the intensity of the second illumination so that the second illumination has the second intensity distribution. The second illumination having the second intensity distribution is irradiated to the photo mask 260. The second illumination passing through the photo mask 260 is irradiated onto the semiconductor substrate 290 on the stage 280 to transcribe the mask pattern of the photo mask 260 into the semiconductor substrate 290, thereby forming the second pattern on the semiconductor substrate 290. Here, since the second pattern has the controlled second intensity distribution, the second pattern may have uniform critical dimensions.

In the present embodiment, after the transmissivity of the light transmission element array 251a is adjusted in accordance with the second intensity distribution, the second exposure process is performed. Thus, the second pattern may have uniform critical dimensions.

According to the embodiments, when a pattern has non-uniform critical dimensions, the light intensity distribution of the illumination is adjusted by controlling the transmissivity of the light transmission elements of the light transmission element array. Thus, the mask pattern of the photo mask is accurately transcribed into the semiconductor substrate so that the pattern on the semiconductor substrate may have uniform critical dimensions.

The light intensity distribution of the illumination may be adjusted by controlling the transmissivity of the light transmission elements of the light transmission element array. The exposure process may be readily controlled in accordance with changes of the critical dimensions of the photo mask so that a feedback of the exposure process is easily carried out.

A cost of re-manufacturing a non uniform photo mask may be avoided and problems resulting from surface defects of the photo mask such as haze may be eliminated.

The foregoing is illustrative of some embodiments and is not to be construed as limiting thereof. Although a few exemplary embodiments have been described, those skilled in the art will readily appreciate that many modifications are possible in the exemplary embodiments without materially departing from the novel teachings and advantages of the invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative and is not to be construed as limited to the specific embodiments disclosed, and that modifications to the disclosed embodiments, as well as other embodiments, are intended to be included within the scope of the appended claims.

What is claimed is:

1. A method of controlling a light intensity, comprising:
obtaining a critical dimension distribution of a first pattern formed on a substrate, the pattern being formed using a first light having a first intensity distribution that is irradiated onto the substrate through a photo mask;
calculating a second intensity distribution according to regions of the photo mask, the calculation based on a relation between the first intensity distribution according to the regions of the photo mask and the critical dimension distribution, the second intensity distribution being used for forming a second pattern having uniform critical dimensions on the substrate; and
converting the first illumination to a second illumination having the second intensity distribution.

2. The method of claim 1, wherein converting the first illumination comprises selectively controlling the first intensity distribution according to the regions of the photo mask.

3. The method of claim 2, wherein controlling the first intensity distribution comprises decreasing a light transmissivity of each of light transmitting elements of a light transmitting element array that has a variable light transmissivity.

4. The method of claim 1, further comprising storing data of the second intensity distribution according to the regions of the photo mask.

5. The method of claim 1, wherein calculating the second intensity distribution comprises:
setting a reference critical dimension among a plurality of critical dimensions in the critical dimension distribution;
comparing the reference critical dimension with the critical dimensions to obtain a critical dimension deviation;
obtaining a variation of the critical dimensions according to the first intensity distribution; and
calculating the second intensity distribution based on the deviation and the variation of the critical dimensions.

6. The method of claim 5, wherein the step of setting a reference critical dimension includes setting a maximum critical dimension, of the plurality of critical dimensions in the critical dimension distribution, as the reference critical dimension.

7. A method of exposing a substrate, comprising:
irradiating in a first exposure process a first illumination having a first intensity distribution onto the substrate through a photo mask to form a first pattern on the substrate;
obtaining a critical dimension distribution of the first pattern;
calculating a second intensity distribution of the first illumination based on a relation between the first intensity distribution and the critical dimension distribution, the second intensity distribution being used for forming a second pattern having uniform critical dimensions on the substrate;
converting the first illumination to a second illumination having the second intensity distribution; and
forming in a second exposure process the second pattern on the substrate using the second illumination.

8. The method of claim 7, wherein converting the first illumination comprises selectively controlling the first intensity distribution according to the regions of the photo mask.

9. The method of claim 8, wherein controlling the first intensity distribution comprises decreasing a light transmissivity of each of light transmission elements in a light transmission element array that has a variable light transmissivity.

10. The method of claim 9, wherein the step of decreasing the light transmissivity of each of the light transmission elements includes controlling a rotation of a polarizing element interposed within a light path of the first illumination.

11. The method of claim 9, wherein the step of decreasing the light transmissivity of each of the light transmission elements includes adjusting a voltage applied to a liquid crystal element interposed within a light path of the first illumination.

12. An apparatus for controlling a light intensity, comprising:
an optical unit for selectively controlling an intensity distribution of a light according to regions of a mask pattern, wherein the light is irradiated onto a photo mask having the mask pattern;
a detecting unit for detecting a critical dimension distribution of a first pattern on a substrate, the first pattern being formed using a first illumination having a first intensity distribution responsive to the photo mask;
a calculating unit for calculating a second intensity distribution based on a relation between the first intensity distribution and the critical dimension distribution, the second intensity distribution being used for forming a second pattern having uniform critical dimensions on the substrate; and
a controlling unit for controlling the optical unit to convert the first illumination into a second illumination having the second intensity distribution.

13. The apparatus of claim 12, wherein the optical unit comprises:
a light transmission element array including a plurality of mesh-type light transmission elements for adjusting the light transmissivity; and
a driver for respectively controlling the light transmissivity of the light transmission elements to vary the first intensity distribution of the first illumination according to the regions of the photo mask.

14. The apparatus of claim 13, wherein each of the light transmission elements includes polarizing devices and wherein the driver includes a plurality of motors for rotating the polarizing devices.

15. The apparatus of claim 13, wherein each of the light transmission elements includes a liquid crystal device and wherein the driver includes a plurality of voltage converters for controlling voltages that are applied to the liquid crystal devices.

16. The apparatus of claim 12, further comprising a data-storing unit for storing data of the second intensity distribution.

17. The apparatus of claim 12, wherein the calculating unit comprises:
a reference setter for setting a reference critical dimension among a plurality of critical dimensions of the critical dimension distribution;
a first calculator for calculating a deviation of the plurality of critical dimensions by comparing the reference critical dimension with each of the plurality of critical dimensions;
a second calculator for calculating a variation of the plurality of critical dimensions based on the first intensity distribution of the first illumination; and
a third calculator for calculating the second intensity distribution based on the deviation and the variation of the critical dimensions.

18. An apparatus for exposing a semiconductor substrate, comprising:
a light source for generating an illumination for irradiating a photo mask having a mask pattern;
an optical unit for selectively controlling an intensity distribution of the illumination according to regions of the mask pattern;
a detecting unit for detecting a critical dimension distribution of a first pattern on a substrate, the first pattern being formed using a first illumination having a first intensity distribution;
a calculating unit for calculating a second intensity distribution of the first illumination based on a relation between the first intensity distribution and the critical dimension distribution, the second intensity distribution being used for forming a second pattern having uniform critical dimensions on the substrate; and
a controlling unit for controlling the optical unit to convert the first illumination into a second illumination having the second intensity distribution.

19. The apparatus of claim 18, wherein the optical unit comprises:
a light transmission element array including light transmission elements that have a variable light transmissivity; and
a driver for respectively controlling the light transmissivity of the light transmission elements to vary the first intensity distribution of the first illumination according to the regions of the photo mask.

20. The apparatus of claim 18, further comprising:
illuminating optics interposed between the light source and the optical unit to transmit the illumination; and
a projecting lens unit interposed between the photo mask and the semiconductor substrate to focus the first and second illumination onto the semiconductor substrate.
